(19) United States
(12) Patent Application Publication
(10) Pub. No.: US 2010/0055898 A1
(43) Pub. Date: Mar. 4, 2010

(54) METHOD FOR FABRICATING AN INTEGRATED CIRCUIT

(76) Inventors: Shuo-Che Chang, Taichung County (TW); Chi-Hsiang Kuo, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/246,451

(22) Filed: Oct. 6, 2008

(30) Foreign Application Priority Data
Sep. 4, 2008 (TW) 097133890

(51) Int. Cl. H01L 21/44

(52) U.S. Cl. 438/653; 257/E21.476

(57) ABSTRACT

A method for fabricating an integrated circuit is provided. A substrate having thereon a first conductive wire and a second conductive wire is provided. A liner is formed on the first conductive wire and second conductive wire. An ashable material layer is filled into a gap between the first conductive wire and second conductive wire. The ashable material layer is then polished to expose a portion of the liner. A cap layer is formed on the ashable material layer and on the exposed liner. A through hole is etched into the cap layer to expose a portion of the ashable material layer. Thereafter, the ashable material layer is removed by way of the through hole.

### BACKGROUND OF THE INVENTION

1. Field of the Invention

The present invention relates, in general, to a method for fabricating an integrated circuit. More particularly, the present invention relates to a method for fabricating an integrated circuit with an air gap.

2. Description of the Prior Art

Semiconductor manufacturers have been trying to shrink transistor size in integrated circuits (IC) to improve chip performance, which leads to the result that the integrated circuit speed is increased and the device density is also greatly increased. However, under the increased IC speed and the device density, the RC delay becomes the dominant factor.

To facilitate further improvements, semiconductor IC manufacturers have been driven by the trend to resort to new materials utilized to reduce the RC delay by either lowering the interconnect wire resistance, or by reducing the capacitance of the inter-layer dielectric (ILD). A significant improvement is achieved by replacing the aluminum (Al) interconnects with copper, which has ˜30% lower resistivity than that of Al. Further advances are facilitated by improving electrical isolation and reducing parasitic capacitance in high density integrated circuits.

Current attempts to improve electrical isolation and reduce parasitic capacitance in high density integrated circuits involve the implementation of low-k dielectric materials such as FSG, HSQ, SiLK™, FLAREK™. To successfully integrate the low K dielectric materials with conventional semiconductor manufacturing processes, several basic characteristics including low dielectric constant, low surface resistivity (>10¹⁵Ω), low compressive or weak tensile (>30 MPa), superior mechanical strength, low moisture absorption and high process compatibility are required.

While the aforesaid materials respectively have a relatively low dielectric constant, they are not normally used in semiconductor manufacturing process due to increased manufacturing complexity and costs, potential reliability problems and low integration between the low-k materials and metals. Therefore, there is a strong need in this industry to provide a method for fabricating an integrated circuit in order to improve the integrated circuit performance.

### SUMMARY OF THE INVENTION

It is one objective of the present invention to provide an improved method for forming an integrated circuit with air gap in order to solve the above-mentioned conventional problems.

To meet these ends, according to one aspect of the present invention, there is provided a method for fabricating an integrated circuit. A substrate having thereon a first conductive wire and a second conductive wire is provided. A liner layer is formed on the first conductive wire and second conductive wire. An ashable material layer is filled into a space between the first conductive wire and second conductive wire. The ashable material layer is then polished to expose a portion of the liner layer. A cap layer is formed on the ashable material layer and on the exposed liner layer. A through hole is extended into the cap layer to expose a portion of the ashable material layer. Thereafter, the ashable material layer is removed by way of the through hole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 are schematic, cross-sectional diagrams showing a method for fabricating an integrated circuit in accordance with one preferred embodiment of this invention.

### DETAILED DESCRIPTION

Without the intention of a limitation, the invention will now be described and illustrated with reference to the preferred embodiments of the present invention.

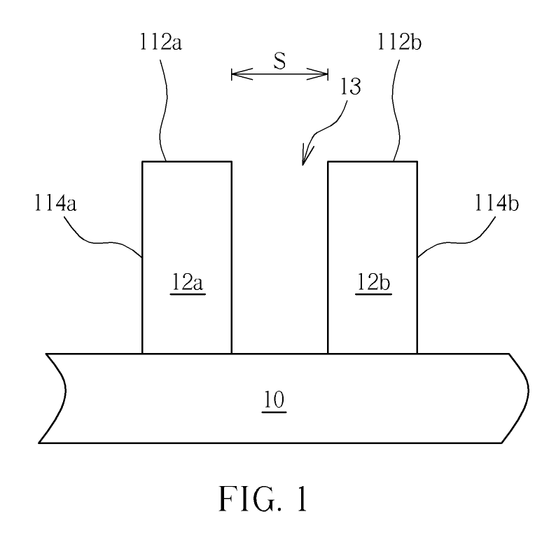

FIG. 1 to FIG. 8 are schematic, cross-sectional diagrams showing a method for fabricating an integrated circuit in accordance with the preferred embodiment of this invention. As shown in FIG. 1, a substrate 10 is provided. A first conductive wire 12a and a second conductive wire 12b are provided on the substrate 10. The first conductive wire 12a is adjacent to the second conductive wire 12b. For example, a space (S) between the first conductive wire 12a and the second conductive wire 12b ranges between 30 nanometers and 500 nanometers. According to this embodiment of the present invention, the first and second conductive wires 12a and 12b are both composed of metal such as aluminum, but not limited thereto.

It is understood that in other embodiments the first and second conductive wires 12a and 12b may be composed of copper or aluminum/copper alloys. According to this embodiment of the present invention, the first conductive wire 12a has an exposed top surface 112a and exposed sidewalls 114a, and the second conductive wire 12b has an exposed top surface 112b and exposed sidewalls 114b.

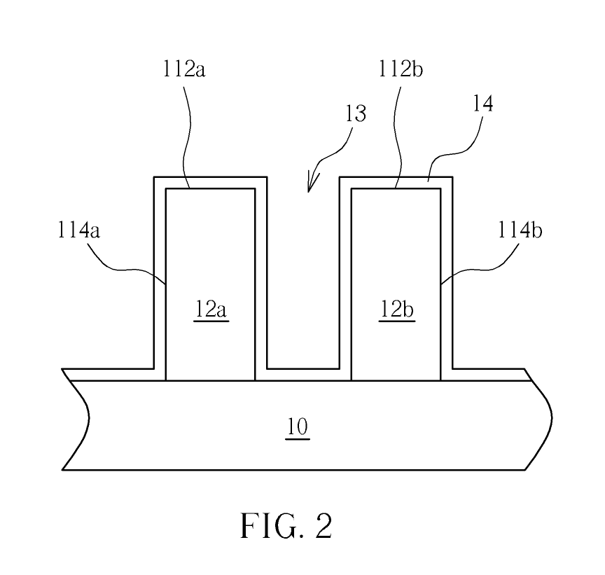

As shown in FIG. 2, subsequently, a chemical vapor deposition (CVD) process is carried out to deposit a conformal liner layer 14 on the top surface 112a and sidewalls 114a of the first conductive wire 12a and the top surface 112b and sidewalls 114b of the second conductive wire 12b. The liner layer 14 also covers the substrate 10.

According to this embodiment of the present invention, the liner layer 14 preferably comprises silicon oxide or silicon nitride and has thickness of 0-1000 angstroms. The thickness of the liner layer 14 is insufficient to fill the space 13 between the first conductive wire 12a and the second conductive wire 12b. In other embodiments, the liner layer 14 may comprise SiO₂, Si₃N₄, SiON, SiC, SiOC, SiCN or any other suitable materials.

According to the preferred embodiment, the liner layer 14 can protect the first conductive wire 12a and the second conductive wire 12b from corrosion. The liner layer 14 also acts as a polishing stop layer during the subsequent chemical mechanical polishing (CMP) process.

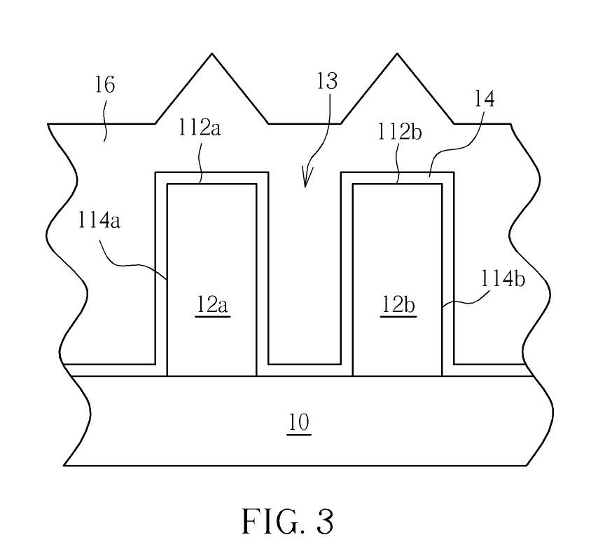

As shown in FIG. 3, an ashable material layer 16 is formed on the liner layer 14. The ashable material layer 16 may comprise carbon layer or fluorine-doped carbon layer. According to the preferred embodiment, the ashable material layer 16 is filled into the space 13 between the first conductive wire 12a and the second conductive wire 12b. The space 13 may be completely or partially filled with the ashable material layer 16. In a situation where the space 13 is not filled with the ashable material layer 16, a void (not shown) may be formed within the space 13.

According to the preferred embodiment of this invention, the ashable material layer 16 may be formed by CVD methods such as PECVD method and HDPCVD method, or spin-on deposition (SOD) methods.

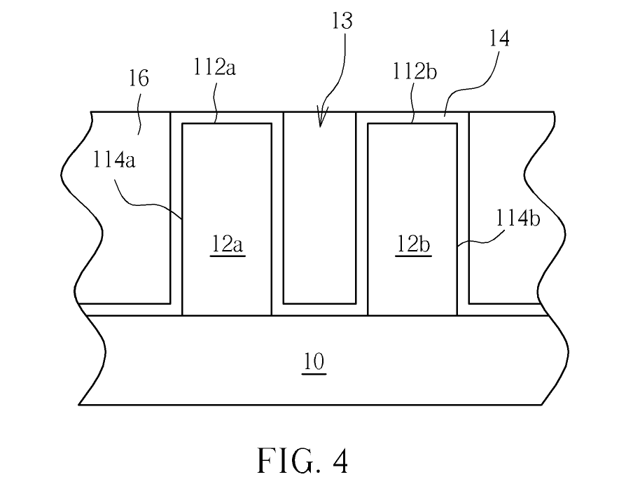

As shown in FIG. 4, subsequently, a planarization process such as CMP process is performed to polish away a portion of the ashable material layer 16, thereby exposing the liner layer 14 on the top surface 112a of the first conductive wire 12a and the liner layer 14 on the top surface 112b of the second conductive wire 12b. As previously mentioned, the liner layer 14 acts as a polishing stop layer during the CMP process. After the CMP process, a top surface of the ashable material layer 16 is substantially coplanar with the exposed surfaces of the liner layer 14.

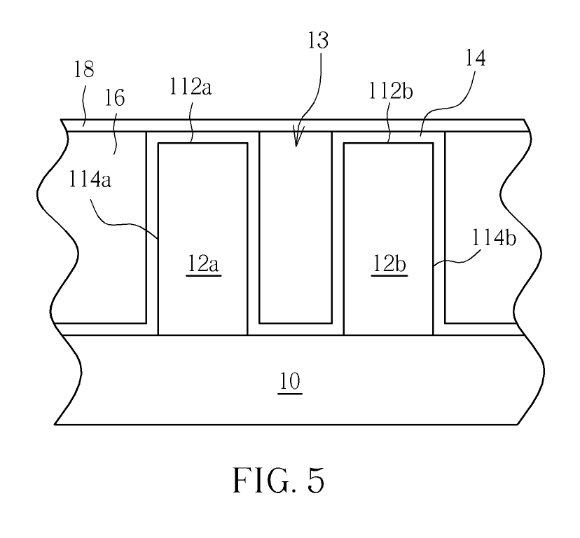

As shown in FIG. 5, a conventional CVD process is carried out to deposit a cap layer 18 on the ashable material layer 16 and on the exposed surfaces of the liner layer 14. According to the preferred embodiment of this invention, the cap layer 18 is a silicon oxide layer. However, the cap layer 18 may be a silicon nitride layer or a low-k dielectric layer.

It is one germane feature of this invention that the ashable material layer 16 in the space 13 must sustain the high temperatures during the CVD deposition of the cap layer 18. Generally, the temperature employed to deposit the cap layer 18 is about 350° C. In this case, the ashable material layer 16 in the space 13 must sustain at least 350° C. In this regard, some organic materials or photoresist materials are inapplicable to the present invention method.

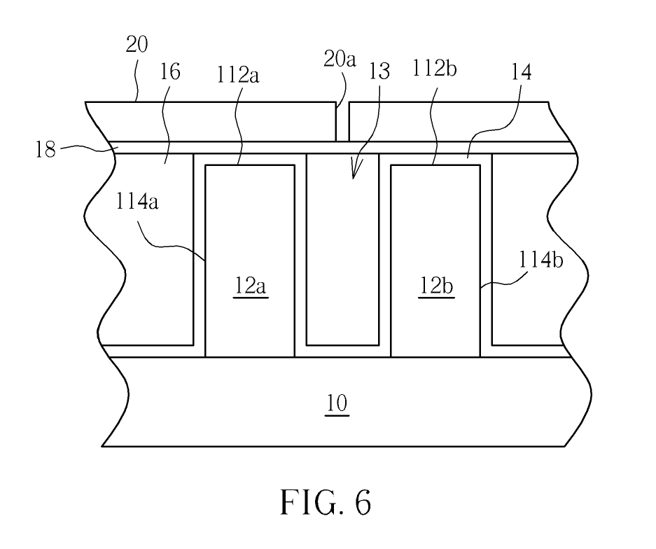

As shown in FIG. 6, a photoresist pattern 20 is formed on the cap layer 18. The photoresist pattern 20 has an aperture 20a exposing a portion of the cap layer 18 directly above the space 13. The method for forming the photoresist pattern 20 may include conventional lithographic process such as photoresist coating, exposure, development and baking.

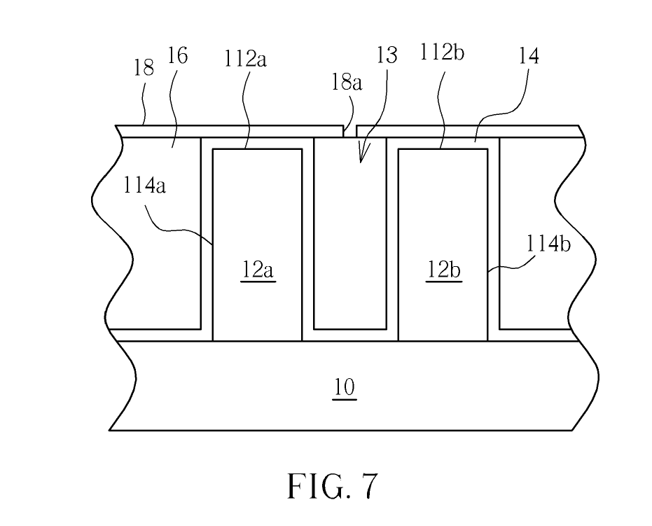

As shown in FIG. 7, thereafter, an etching process such as a dry etching process is performed to etch the cap layer 18 through the aperture 20a of the photoresist pattern 20, thereby forming a through hole 18a in the cap layer 18. The through hole 18a exposes a portion of the ashable material layer 16. The photoresist pattern 20 is then stripped off.

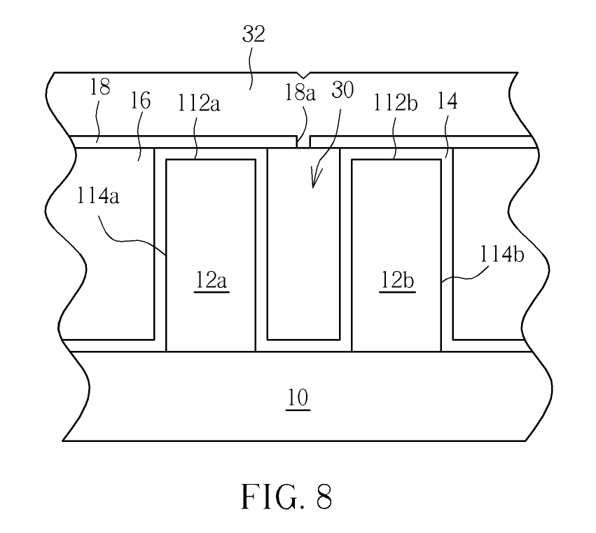

As shown in FIG. 8, an ashing process is carried out. For example, oxygen plasma is utilized to completely remove the ashable material layer 16 between the first conductive wire 12a and the second conductive wire 12b by way of the through hole 18a of the cap layer 18, thereby forming an air gap 30 between the first conductive wire 12a and the second conductive wire 12b. Subsequently, a CVD process is performed to form a dielectric layer 32 over the cap layer 18. The dielectric layer 32 seals the through hole 18a of the cap layer 18 thereby forming a hermetic air gap 30. According to the preferred embodiment of this invention, the dielectric layer 32 may be silicon oxide or low-k dielectric materials. In other embodiments, the deposition of the dielectric layer 32 may be implemented concurrently with the aforesaid ashing process.

The method for fabricating the integrated circuit structure of the present invention has at least the following advantages: (1) The method is completely compatible with current integrated circuit manufacturing processes and no additional investment or development of new equipment is required; (2) The method is cost effective; and (3) The method can provide maximized and unified air gap structure between metal interconnection lines, which is capable of effectively reducing RC delay and improving performance of the integrated circuit device.

Those skilled in the art will readily observe that numerous modifications and alterations of the device and method may be made while retaining the teachings of the invention.

What is claimed is:

1. A method for fabricating an integrated circuit, comprising the steps of:
providing a substrate having thereon a first conductive wire and a second conductive wire;
forming a material layer on the substrate to cover the first conductive wire and the second conductive wire and fill into a space between the first conductive wire and the second conductive wire;
masking the material layer; and
removing the material layer.

2. The method of claim 1, wherein prior to the material layer formation step, a liner layer is formed on the substrate.

3. The method of claim 2, wherein the liner layer comprises SiO₂, Si₃N₄, SiON, SiC, SiOC or SiCN.

4. The method of claim 2, wherein the liner layer protects the first and the second conductive wires from corrosion and acts as a polishing stop layer.

5. The method of claim 1, wherein the material layer selectively comprises carbon layer and fluorine-doped carbon layer.

6. The method of claim 1, wherein the space is filled with the material layer.

7. The method of claim 1, wherein the material layer sustains at least 350° C.

8. The method of claim 1, wherein the material layer is removed by using oxygen plasma.

9. The method of claim 1, further comprising the following step after the material layer removing step:
forming a dielectric layer over the substrate to form a hermetic air gap between the first conductive wire and the second conductive wire.

10. The method of claim 9, wherein the dielectric layer selectively comprises silicon oxide and low-k dielectric materials.

11. A method for fabricating an integrated circuit, comprising the steps of:
providing a substrate having thereon a first conductive wire and a second conductive wire;
forming a liner layer on the first conductive wire and the second conductive wire;
forming an ashable material layer on the liner layer and the ashable material layer filling into a space between the first conductive wire and the second conductive wire;
performing a planarization process to polish away a portion of the ashable material layer, thereby exposing a portion of the liner layer;
forming a cap layer on the ashable material layer and on the exposed liner layer;
forming a through hole in the cap layer to expose a portion of the ashable material layer; and
removing the ashable material layer by way of the through hole, thereby forming an air gap between the first conductive wire and the second conductive wire.

12. The method of claim 11, wherein the liner layer comprises SiO₂, Si₃N₄, SiON, SiC, SiOC or SiCN.

13. The method of claim 11, wherein the liner layer protects the first and the second conductive wires from corrosion and acts as a polishing stop layer.

14. The method of claim 11, wherein the ashable material layer comprises carbon layer or fluorine-doped carbon layer.

15. The method of claim 14, wherein the space is filled with the material layer.

16. The method of claim 11, wherein the cap layer selectively comprises silicon oxide, silicon nitride and low-k materials.

17. The method of claim 11, wherein the ashable material layer sustains at least 350° C.

18. The method of claim 11, wherein the ashable material layer is removed by using oxygen plasma.

19. The method of claim 11 further comprising the following step after the ashable material layer removing step:
forming a dielectric layer over the substrate to seal the through hole.

20. The method of claim 19, wherein the dielectric layer selectively comprises silicon oxide or low-k dielectric materials.
